(19) United States
(12) Patent Application Publication
(10) Pub. No.: US 2024/0421182 A1
(43) Pub. Date: Dec. 19, 2024

(54) LEAKAGE REDUCTION FOR CONTINUOUS ACTIVE DESIGNS

(71) Applicant: International Business Machines Corporation, Armonk, NY (US)

(72) Inventors: Jason J Stuffle, Burlington, VT (US); Albert M. Chu, Nashua, NH (US); Charles Nicholas Perez, Burlington, VT (US)

(21) Appl. No.: 18/336,683

(22) Filed: Jun. 16, 2023

(51) Int. Cl. H01L 29/06; G11C 16/34; H01L 27/02; H01L 27/092; H01L 29/08

(52) U.S. Cl. CPC H01L 29/0607; G11C 16/3427; H01L 27/0207; H01L 27/0922; H01L 29/0696; H01L 29/0869; H01L 29/0886

(57) ABSTRACT

A device comprises memory configured to store program instructions, and processing circuitry, coupled to the memory, and configured to execute the program instructions to perform a process to limit current leakage. The processing circuitry is configured to receive an input of an initial layout of a semiconductor structure comprising a plurality of cells, identify a plurality of edge source/drain regions in respective ones of the cells, determine respective electrical configurations for the edge source/drain regions, compute respective values associated with current leakage for adjacent cells in the initial layout and in a plurality of alternative layouts of the semiconductor structure based at least in part on the respective electrical configurations for the edge source/drain regions, and identify at least one alternative layout of the plurality of alternative layouts to the initial layout that results in at least a reduction of total current leakage from the initial layout.

### BACKGROUND

This disclosure relates generally to management of semiconductor device configurations and, in particular, to techniques for optimizing cell placement in semiconductor structures to reduce current leakage from gate-tie-down structures. Gate tie-down structures provide a connection between a gate contact and a power rail. Gate contacts provide an electrical connection to gate structures of transistors, and source/drain contacts provide electrical connections to source/drain regions of transistors. A gate-tie-down structure electrically connects a gate structure to a power rail.

The semiconductor industry is moving away from single diffusion break (SDB) structures to gate tie-down (continuous active) structures. SDB structures include isolation regions between source/drain regions to prevent current leakage. Gate tie-down structures typically lack isolation regions between source/drain regions. As a result, there is a concern with continuous active structures that the tied-off gates will cause increased device leakage.

### SUMMARY

Exemplary embodiments of the disclosure include techniques for evaluating cell layouts of semiconductor structures and determining alternative cell layouts which reduce current leakage associated with adjacent cells corresponding to gate tie-down structures. For example, an exemplary embodiment includes a device which comprises memory that is configured to store program instructions, and processing circuitry, coupled to the memory, and configured to execute the program instructions to perform a process to limit current leakage. In performing the process, the processing circuitry is configured to receive an input of an initial layout of a semiconductor structure comprising a plurality of cells, identify a plurality of edge source/drain regions in respective ones of the plurality of cells, determine respective electrical configurations for the plurality of edge source/drain regions, compute respective values associated with current leakage for adjacent cells of the plurality of cells in the initial layout and in a plurality of alternative layouts of the semiconductor structure based at least in part on the respective electrical configurations for the plurality of edge source/drain regions, and identify at least one alternative layout of the plurality of alternative layouts to the initial layout, where the at least one alternative layout results in at least a reduction of total current leakage from the initial layout.

As may be combined with the preceding paragraph, the respective electrical configurations for the plurality of edge source/drain regions can include, for example, a power connection, a signal connection and/or a floating configuration.

As may be combined with the preceding paragraphs, in computing the respective values associated with the current leakage for the adjacent cells, the processing circuitry may be further configured to identify electrical configurations of respective edge source/drain regions of a plurality of pairs of the adjacent cells. The respective values associated with current leakage for the adjacent cells can be computed based on the electrical configurations of the respective edge source/drain regions of the plurality of pairs of the adjacent cells. An abstract view of the electrical configurations of the respective edge source/drain regions of the plurality of pairs of the adjacent cells can be generated.

As may be combined with the preceding paragraphs, the respective values associated with the current leakage for the adjacent cells can vary based on a type and a combination of the electrical configurations of the respective edge source/drain regions of the plurality of pairs of the adjacent cells. In addition, in computing the respective values associated with the current leakage for the adjacent cells, the processing circuitry may be configured to identify a plurality of gate tie-down structures in the initial layout and in the plurality of alternative layouts, where the plurality of edge source/drain regions correspond to at least a subset of the plurality of gate tic-down structures.

As may be combined with the preceding paragraphs, in identifying the at least one alternative layout of the plurality of alternative layouts to the initial layout, the processing circuitry may be configured to further base the identification of the at least one alternative layout on one or more parameters in addition to the reduction of the total current leakage. The one or more parameters may comprise at least one of wire length, frequency and area of one or more devices in the semiconductor structure.

As may be combined with the preceding paragraphs, the processing circuitry can be further configured to compute a total current leakage of the at least one alternative layout, where the computing of the total current leakage of the at least one alternative layout includes identifying a plurality of gate tie-down structures in the at least one alternative layout, identifying respective ones of the plurality of edge source/drain regions corresponding to at least a subset of the plurality of gate tie-down structures, identifying electrical configurations of the respective ones of the plurality of edge source/drain regions of a plurality of pairs of adjacent cells in the at least one alternative layout, computing leakage values for the respective ones of the plurality of pairs of the adjacent cells in the at least one alternative layout based at least in part on the electrical configurations of the respective ones of the plurality of edge source/drain regions, and adding the leakage values for the respective ones of the plurality of pairs of the adjacent cells in the at least one alternative layout.

As may be combined with the preceding paragraphs, the processing circuitry can be configured to apply the at least one alternative layout to a semiconductor manufacturing system adapted to fabricate the semiconductor structure based at least in part on the at least one alternative layout.

Advantageously, the embodiments analyze gate tie-down structures and source/drain connections at cell boundaries to determine cell placement that will minimize current leakage. The embodiments identify edge source/drain regions of multiple cells in a cell layout and their corresponding electrical configurations (e.g., power connection, signal connection, floating). The embodiments execute a cost function to determine configurations of adjacent cells and corresponding electrical configurations that will prevent or cause reduced leakage in continuous area structures.

Another exemplary embodiment includes a system which comprises a computing system, where the computing system comprises memory that is configured to store program instructions, and processing circuitry, coupled to the memory, and configured to execute the program instructions to perform a process to limit current leakage. In performing the process, the processing circuitry is configured to receive an input of an initial layout of a semiconductor structure comprising a plurality of cells, identify a plurality of edge source/drain regions in respective ones of the plurality of cells, determine respective electrical configurations for the plurality of edge source/drain regions, compute respective values associated with current leakage for adjacent cells of the plurality of cells in the initial layout and in a plurality of alternative layouts of the semiconductor structure based at least in part on the respective electrical configurations for the plurality of edge source/drain regions, and identify at least one alternative layout of the plurality of alternative layouts to the initial layout, where the at least one alternative layout results in at least a reduction of total current leakage from the initial layout.

As may be combined with the preceding paragraphs, the respective electrical configurations for the plurality of edge source/drain regions include a power connection, a signal connection and/or a floating configuration.

As may be combined with the preceding paragraphs, in computing the respective values associated with the current leakage for the adjacent cells, the processing circuitry may be configured to identify electrical configurations of respective edge source/drain regions of a plurality of pairs of the adjacent cells, where the respective values associated with current leakage for the adjacent cells are computed based on the electrical configurations of the respective edge source/drain regions of the plurality of pairs of the adjacent cells.

As may be combined with the preceding paragraphs, in computing the respective values associated with the current leakage for the adjacent cells, the processing circuitry can be configured to identify a plurality of gate tie-down structures in the initial layout and in the plurality of alternative layouts, and the plurality of edge source/drain regions may correspond to at least a subset of the plurality of gate tie-down structures.

As may be combined with the preceding paragraphs, the processing circuitry may be further configured to compute a total current leakage of the at least one alternative layout, where the computing of the total current leakage of the at least one alternative layout comprises identifying a plurality of gate tie-down structures in the at least one alternative layout, identifying respective ones of the plurality of edge source/drain regions corresponding to at least a subset of the plurality of gate tie-down structures, identifying electrical configurations of the respective ones of the plurality of edge source/drain regions of a plurality of pairs of adjacent cells in the at least one alternative layout, computing leakage values for the respective ones of the plurality of pairs of the adjacent cells in the at least one alternative layout based at least in part on the electrical configurations of the respective ones of the plurality of edge source/drain regions, and adding the leakage values for the respective ones of the plurality of pairs of the adjacent cells in the at least one alternative layout.

As may be combined with the preceding paragraphs, the system may further include a semiconductor manufacturing system adapted to fabricate the semiconductor structure based at least in part on the at least one alternative layout.

Another exemplary embodiment includes a computer program product for performing a process to limit current leakage. The computer program product comprises one or more computer readable storage media, and program instructions collectively stored on the one or more computer readable storage media. The program instructions comprise program instructions to receive an input of an initial layout of a semiconductor structure comprising a plurality of cells, program instructions to identify a plurality of edge source/drain regions in respective ones of the plurality of cells, program instructions to determine respective electrical configurations for the plurality of edge source/drain regions, program instructions to compute respective values associated with current leakage for adjacent cells of the plurality of cells in the initial layout and in a plurality of alternative layouts of the semiconductor structure based at least in part on the respective electrical configurations for the plurality of edge source/drain regions, and program instructions to identify at least one alternative layout of the plurality of alternative layouts to the initial layout, where the at least one alternative layout results in at least a reduction of total current leakage from the initial layout.

As may be combined with the preceding paragraphs, the respective electrical configurations for the plurality of edge source/drain regions comprise at least one of a power connection, a signal connection and a floating configuration.

As may be combined with the preceding paragraphs, the program instructions to compute the respective values associated with the current leakage for the adjacent cells may include program instructions to identify electrical configurations of respective edge source/drain regions of a plurality of pairs of the adjacent cells, where the respective values associated with current leakage for the adjacent cells are computed based on the electrical configurations of the respective edge source/drain regions of the plurality of pairs of the adjacent cells.

As may be combined with the preceding paragraphs, the program instructions to compute the respective values associated with the current leakage for the adjacent cells may include program instructions to identify a plurality of gate tie-down structures in the initial layout and in the plurality of alternative layouts, where the plurality of edge source/drain regions correspond to at least a subset of the plurality of gate tie-down structures.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure including gate tie-down structures causing leakage, according to an exemplary embodiment of the disclosure.

FIG. 2 schematically illustrates a process for generating cell layouts that limit leakage of devices in continuous active configurations, according to an exemplary embodiment of the disclosure.

FIG. 3A schematically illustrates a cell layout of adjacent cells with edge source/drain regions corresponding to gate tie-down structures where there is a signal to signal abutment and a power to signal abutment, according to an exemplary embodiment of the disclosure.

FIG. 3B schematically illustrates a cell layout of adjacent cells with edge source/drain regions corresponding to gate tie-down structures where there are power to float abutments, according to an exemplary embodiment of the disclosure.

FIG. 3C schematically illustrates a cell layout of adjacent cells with edge source/drain regions corresponding to gate tie-down structures where there are power to power abutments, according to an exemplary embodiment of the disclosure.

FIG. 4A schematically illustrates a semiconductor structure including a cell with a plurality of edge source/drain regions, according to an exemplary embodiment of the disclosure.

FIG. 4B depicts an example abstract view of the cell in FIG. 4A including the electrical configurations of the edge source/drain regions, according to an exemplary embodiment of the disclosure.

FIGS. 4C, 4D and 4E depict example abstract views of adjacent cells of a semiconductor structure along with leakage costs associated with the electrical configurations of the edge source/drain regions, according to an exemplary embodiment of the disclosure.

FIG. 5 schematically illustrates modifications to a cell layout to prevent leakage from a gate tie-down structure, according to an exemplary embodiment of the disclosure.

FIG. 6 schematically illustrates a computing system that is configured to generate cell layouts that limit leakage of devices in continuous active configurations, according to an exemplary embodiment of the disclosure.

FIG. 7 schematically illustrates a process for generating cell layouts that limit leakage of devices in continuous active configurations, according to an exemplary embodiment of the disclosure.

FIG. 8 schematically illustrates an exemplary architecture of a computing environment for generating cell layouts that limit leakage of devices in continuous active configurations, according to an exemplary embodiment of the disclosure.

### DETAILED DESCRIPTION

Exemplary embodiments of the disclosure will now be described in further detail with regard to limiting current leakage in continuous active designs. More specifically, exemplary embodiments as described herein include techniques for analysis of edge regions of adjacent cells in semiconductor structure cell layouts and determining alternative cell layouts which reduce current leakage associated with adjacent cells corresponding to gate tie-down structures.

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, engine, layer or the like, performing one or more functions or otherwise providing some functionality, is intended to encompass embodiments wherein the circuit, structure, element, component, engine, layer or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, engine, layer, etc., is defined to be configured to provide a specific functionality, it is intended to cover, but not be limited to, embodiments where the circuit, structure, element, component, engine, layer, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, engine, layer, etc., is in a non-operational state (e.g., not connected nor otherwise deployed in a system, not powered on, not receiving an input, and/or not producing an output) or in a partial operational state.

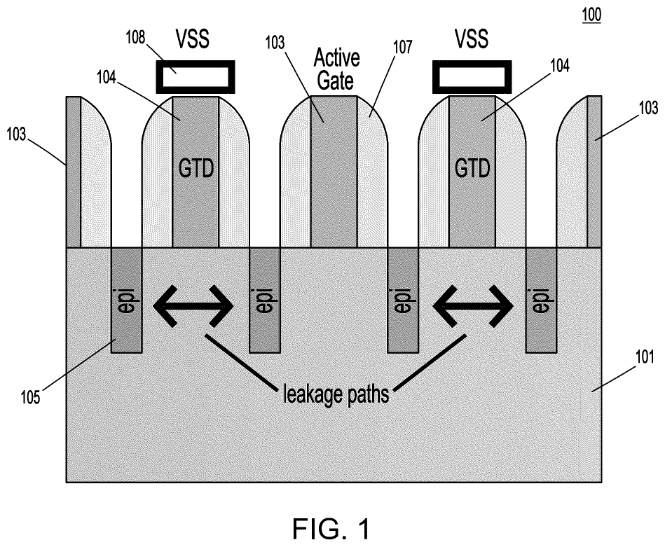

FIG. 1 depicts a cross-sectional view of a semiconductor structure 100 including gate tie-down (GTD) structures 104 causing leakage. A semiconductor substrate 101 comprises semiconductor material including, but not limited to, silicon (Si), III-V, II-V compound semiconductor materials or other like semiconductor materials. In addition, multiple layers of the semiconductor materials can be used as the semiconductor material of the semiconductor substrate 101.

In illustrative embodiments, each active gate structure 103 includes a metal gate portion including a work-function metal (WFM) layer, including but not necessarily limited to, for a p-type field-effect transistor (pFET), titanium nitride (TiN), tantalum nitride (TaN) or ruthenium (Ru), and for an n-type field-effect transistor (nFET), TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer. It should be appreciated that various other materials may be used for the metal gate portions as desired. Alternatively, an active gate structure 103 may include non-metal material such as, for example, polysilicon, instead of the metal gate portion. The GTD structures 104 may comprise the same or similar materials to those of the active gate structures 103.

Epitaxial layers (EPI) comprise source/drain regions 105. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material.

Gate spacers 107 are positioned on opposite lateral sides of the active gate structures 103 and of the GTD structures 104. The gate spacers 107 are formed from, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof. The gate spacers 107 can be formed by any suitable techniques such as deposition followed by directional etching. Deposition may include, but is not limited to, atomic layer deposition (ALD) or chemical vapor deposition (CVD). Directional etching may include but is not limited to, reactive ion etching (RIE).

As noted herein above, gate tie-down structures provide a connection between a gate contact and a power rail. For example, referring to FIG. 1, the GTD structures 104 are connected to a source voltage (VSS) 108 from, for example, a power rail, and to a gate contact (not shown) providing an electrical connection to gate structures of transistors. A power rail may be formed in a backside dielectric layer (e.g., inter-layer dielectric (ILD) layer) by forming one or more trenches in the backside dielectric layer and filling the trenches with conductive material. Power rails can be connected to a source voltage (VSS), a drain voltage (VDD) and/or ground (GND).

Unlike SDB structures, which include isolation regions between source/drain regions 105 to prevent current leakage, with continuous active configurations comprising GTD structures 104, isolation regions are not included between source/drain regions 105. As a result, as shown in FIG. 1, there are leakage paths between source/drain regions 105 corresponding to GTD structures 104.

As noted above, exemplary embodiments of the disclosure include techniques to identify source/drain edge regions of adjacent cells in semiconductor structure cell layouts and determine alternative cell layouts which reduce current leakage associated with adjacent cells including source/drain regions corresponding to the gate tie-down structures.

It is to be noted that the term “cell” as used herein is to be broadly construed to refer to, for example, a group of transistor and interconnect structures that provides a Boolean logic function (e.g., AND, OR, XOR, XNOR, inverters) and/or a storage function (e.g., flipflop or latch). In a non-limiting example, a cell is a representation of the elemental NAND, NOR and XOR Boolean function, although cells of greater complexity can be used. The Boolean logic function of a cell may be referred to a logical view of the cell, where functional behavior is captured in the form of, for example, a truth table, Boolean algebraic equation and/or a state transition table. In some embodiments, a cell comprises a representation of one or more components within a schematic diagram or physical layout of an electronic circuit. Cell-based design methodology permits designers to analyze chip designs at multiple levels of abstraction to analyze logical function and/or physical implementation.

The design of a cell can be developed at a transistor level, in the form of, for example, a transistor netlist or schematic view. As used herein, a “netlist” is to be broadly construed to refer to, for example, a nodal description of transistors, their connections, and their terminals. A netlist can include a description of the connectivity of an electronic circuit, and may include, for example, a list of electronic components in a circuit and a list of the nodes to which they are connected.

It is to be noted that the term “cell layout” or “layout” as used herein is to be broadly construed to refer to, for example, a representation of an arrangement of a plurality of cells in connection with a semiconductor structure, where the semiconductor structure can include, but is not necessarily limited to, one or more semiconductor devices, integrated circuits, chips, printed circuit boards (PCBs), etc.

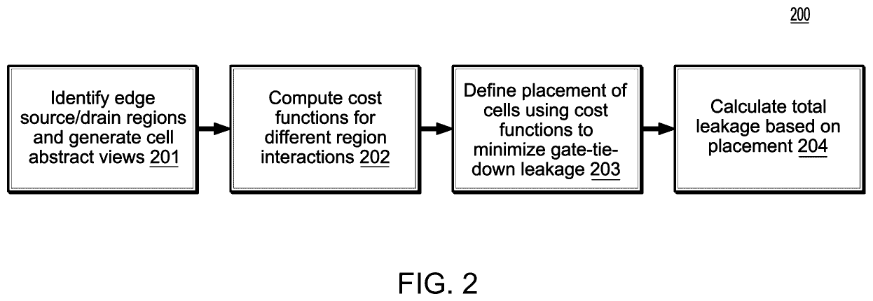

FIG. 2 schematically illustrates a process 200 for generating cell layouts that limit leakage of devices in continuous active configurations. Referring to FIG. 2, at block 201, given an input of a cell layout of a semiconductor structure, edge source/drain regions are identified and cell abstract views are generated. For example, in a cell layout including a plurality of cells, source/drain regions at edges of respective cells of the cell layout are identified.

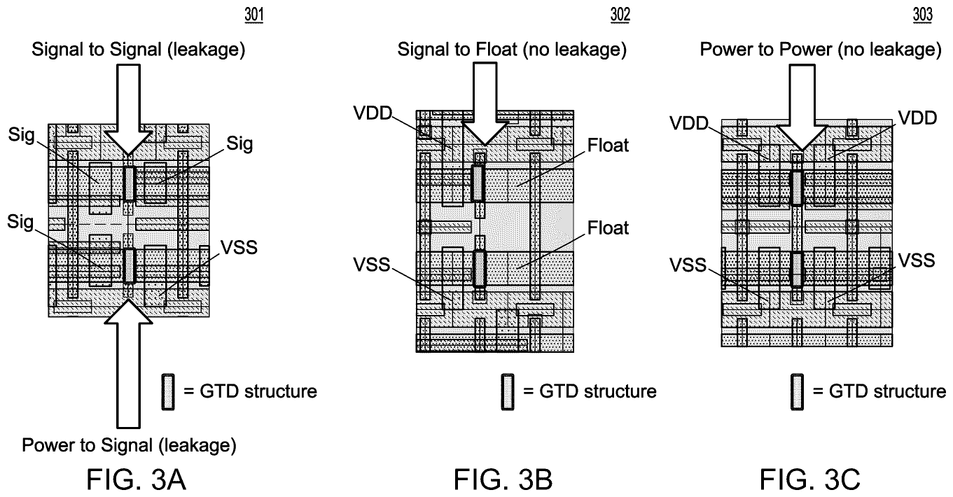

Referring to FIGS. 3A-3C, cell layouts 301, 302 and 303 of adjacent cells with edge source/drain regions corresponding to gate tie-down structures are shown. The amount of chip leakage from gate tie-down structures depends on cell placement (e.g., the configuration of adjacent cells) in a cell layout. Gate tie-down structures at cell boundaries may have leakage current depending on the electrical configurations of the edge source/drain regions. For example, the cell layout 301 in FIG. 3A depicts edge source/drain regions where there is a signal to signal abutment and a power to signal abutment. In more detail, in the cell layout 301, two edge source/drain regions of a first set of respective edge source/drain regions of adjacent cells have signal connections (Sig) in a signal to signal abutment. Additionally, in the cell layout 301, a second set of respective edge source/drain regions of adjacent cells includes a first edge source/drain region with a signal connection (Sig) and a second edge source/drain region with a power connection (VSS) in a power to signal abutment.

The cell layout 302 in FIG. 3B depicts edge source/drain regions where there are power to float abutments. In more detail, in the cell layout 302, a first set of respective edge source/drain regions of adjacent cells includes a first edge source/drain region with a power connection (drain voltage (VDD)) and a second edge source/drain region that is floating, and a second set of respective edge source/drain regions of the adjacent cells includes a third edge source/drain region with a power connection (VSS) and a fourth edge source/drain region that is floating.

The cell layout 303 in FIG. 3C depicts edge source/drain regions where there are power to power abutments. In more detail, in the cell layout 303, a first set of respective edge source/drain regions of adjacent cells includes first and second edge source/drain regions with power connections (VDD), and a second set of respective edge source/drain regions of the adjacent cells includes third and fourth edge source/drain regions with power connections (VSS).

The signal to signal and power to signal abutments result in current leakage, while the power to float and power to power abutments do not result in current leakage. Accordingly, the type of electrical configurations of the edge source/drain regions of adjacent cells affects whether there is leakage between edge source/drain regions corresponding to gate tie-down structures.

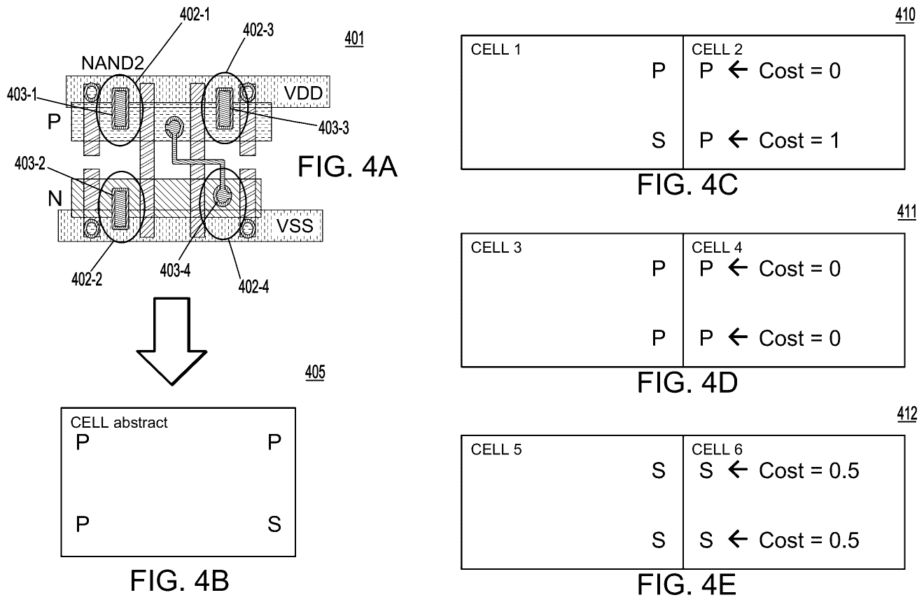

In illustrative embodiments, following identification of the edge source/drain regions in respective ones of a plurality of cells in a cell layout, the respective electrical configurations (e.g., power connection, signal connection, floating configuration) of the edge source/drain regions are determined. Referring back to block 201 of FIG. 2, abstract views of the cells are generated based on the determined electrical configurations of the edge source/drain regions. Referring to FIG. 4A, a cell 401 of a semiconductor structure with a plurality of edge source/drain regions 402-1, 402-2, 402-3 and 402-4 (collectively “edge source/drain regions 402”) is shown. The edge source/drain regions 402-1, 402-2, 402-3 and 402-4 respectively correspond to gate tie-down structures 403-1, 403-2, 403-3 and 403-4 (collectively “gate tie-down structures 403”). FIG. 4B depicts an example abstract view 405 of the cell 401 in FIG. 4A, including the electrical configurations of the edge source/drain regions 402. As can be seen in the abstract view 405, the edge source/drain region 402-1 and corresponding gate tie-down structure 403-1 correspond to a power connection (P) (VDD), the edge source/drain region 402-2 and corresponding gate tie-down structure 403-2 correspond to a power connection (P) (VSS), the edge source/drain region 402-3 and corresponding gate tie-down structure 403-3 correspond to a power connection (P) (VDD), and the edge source/drain region 402-4 and corresponding gate tie-down structure 403-4 correspond to a signal connection(S).

Referring back to the process 200 for generating cell layouts that limit leakage of devices in continuous active configurations in FIG. 2, at block 202, cost functions for different region interactions are computed. The cost functions comprise respective values associated with current leakage for adjacent cells based at least in part on the respective electrical configurations for the plurality of edge source/drain regions. For example, for edge source/drain regions of adjacent cells each having power connection, the cost function can be 0 because there is no leakage in this situation. For edge source/drain regions of adjacent cells having respective signal and power connections, the cost function can be 1 because there is leakage in this situation. For edge source/drain regions of adjacent cells each having signal connection, the cost function can be 0.5 because there is leakage in this situation, but the leakage is less than for signal to power abutments. The cost function is assigned based at least in part on the electrical configurations of the abutting source/drain regions of adjacent cells in a cell layout.

FIGS. 4C, 4D and 4E depict example abstract views 410, 411 and 412 of adjacent cells of a semiconductor structure along with leakage costs associated with the electrical configurations of the edge source/drain regions. As can be seen in FIG. 4C, a first cell (cell 1) has edge source/drain regions with power (P) and signal(S) connections, while an adjacent second cell (cell 2) has edge source/drain regions that both have power (P) connections. The cost is depicted as 0 for the power to power abutment and 1 for the signal to power abutment. In FIG. 4D, a third cell (cell 3) and an adjacent fourth cell (cell 4) each have two edge source/drain regions with power (P) connections. The cost is depicted as 0 for both the power to power abutments. In FIG. 4E, a fifth cell (cell 5) and an adjacent sixth cell (cell 6) each have two edge source/drain regions with signal(S) connections. The cost is depicted as 0.5 for both the signal to signal abutments. As can be understood, the respective cost function values associated with the current leakage for the adjacent cells vary based on a type and a combination of the electrical configurations of the respective edge source/drain regions of the pairs of the adjacent cells. The cost function values are example values, and the embodiments are not limited to the values used herein.

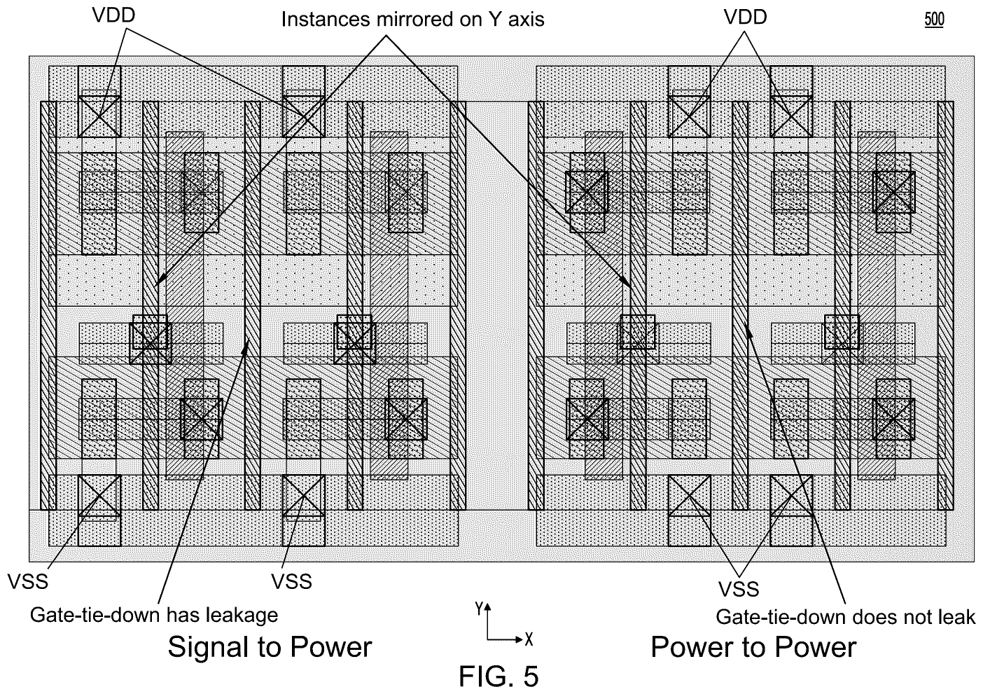

Referring back to the process 200 for generating cell layouts that limit leakage of devices in continuous active configurations in FIG. 2, at block 203, placement of the cells in a cell layout is defined using the cost function to minimize leakage associated with gate tie-down structures corresponding to the edge source/drain regions. In more detail, respective values associated with current leakage for adjacent cells of a plurality of cells in an initial layout and in a plurality of alternative layouts of a semiconductor structure are computed based at least in part on the respective electrical configurations for the plurality of edge source/drain regions. At least one alternative layout of the plurality of alternative layouts to the initial layout is identified, wherein the at least one alternative layout results in at least a reduction of total current leakage from the initial layout. For example, FIG. 5 schematically illustrates modifications to a portion of a cell layout 500 to prevent leakage from a gate tie-down structure. As can be seen in FIG. 5, in a first configuration, edge source/drain regions of adjacent cells are in a signal to power configuration. In the second configuration, by mirroring instances around the vertical (Y axis), the configuration of the edge source/drain regions of the adjacent cells is changed to a power to power abutment resulting in no leakage. On a much larger scale (e.g., thousands of cells in a cell layout and hundreds of thousands to millions, billions, etc. of permutations for different cell layouts), the embodiments recommend alternative layouts that result in at least a reduction of total current leakage from an initial layout. For example, in non-limiting illustrative embodiments, a cell placement algorithm generates cell placement solutions that yield the lowest cost function, when accounting for gate tie-down leakage impact.

In some embodiments, the identification of the identification of alternative layouts is based on one or more parameters in addition to the reduction of the current leakage caused by the gate tie-down structures. The one or more parameters include, but are not necessarily limited to, wire length, frequency and/or area of one or more devices in a semiconductor structure.

Referring back to the process 200 for generating cell layouts that limit leakage of devices in continuous active configurations in FIG. 2, at block 204, total leakage based on the defined placement is calculated. In more detail, a total current leakage of an alternative cell layout having a continuous active configuration is computed by, for example, identifying a plurality of gate tie-down structures in the alternative layout, identifying respective ones of a plurality of edge source/drain regions corresponding to at least a subset of the plurality of gate tie-down structures, identifying electrical configurations of the respective ones of the plurality of edge source/drain regions of a plurality of pairs of adjacent cells in the alternative layout, computing leakage values for the respective ones of the plurality of pairs of the adjacent cells in the alternative layout based at least in part on the electrical configurations of the respective ones of the plurality of edge source/drain regions, and adding the leakage values for the respective ones of the plurality of pairs of the adjacent cells in the alternative layout.

In accordance with illustrative embodiments, a netlist for the alternative layout is extracted, the tied-off gates (e.g., gate tie-down structures) are identified, and the source/drain regions corresponding to the gate tied-off gates are determined. If the source/drain regions are in, for example, a power to power abutment, power to floating abutment, signal to floating abutment or a floating to floating abutment, the leakage is defined as X. If the source/drain regions are in, for example, a signal to signal abutment, the leakage is defined as Y, and if the source/drain regions are in, for example, a power to signal abutment, the leakage is defined as Z, where leakage values are X<Y<Z (e.g., 0<0.5<1). The total leakage equals the sum of the leakage from all tied off gates. In illustrative embodiments, the total leakage is based on not only abutments caused by edge source/drain regions of adjacent cells, but also on electrical configurations of pairs of adjacent source/drain regions within the cells of a cell layout that may result in leakage.

In addition to standard FET structures, the gate-tie-down leakage optimization techniques described herein can also be implemented in connection with stacked FET designs. Additionally, the gate-tie-down leakage optimization techniques described herein apply to frontside and backside power distribution networks. In some embodiments, cell layouts may be structured with power and/or ground connections on left and right diffusion edges to reduce gate-tic-down leakage.

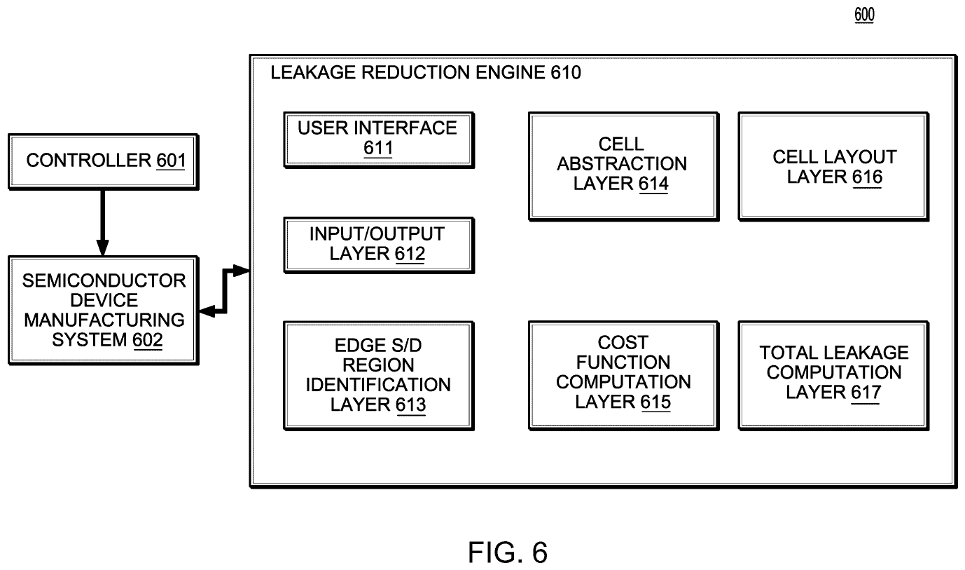

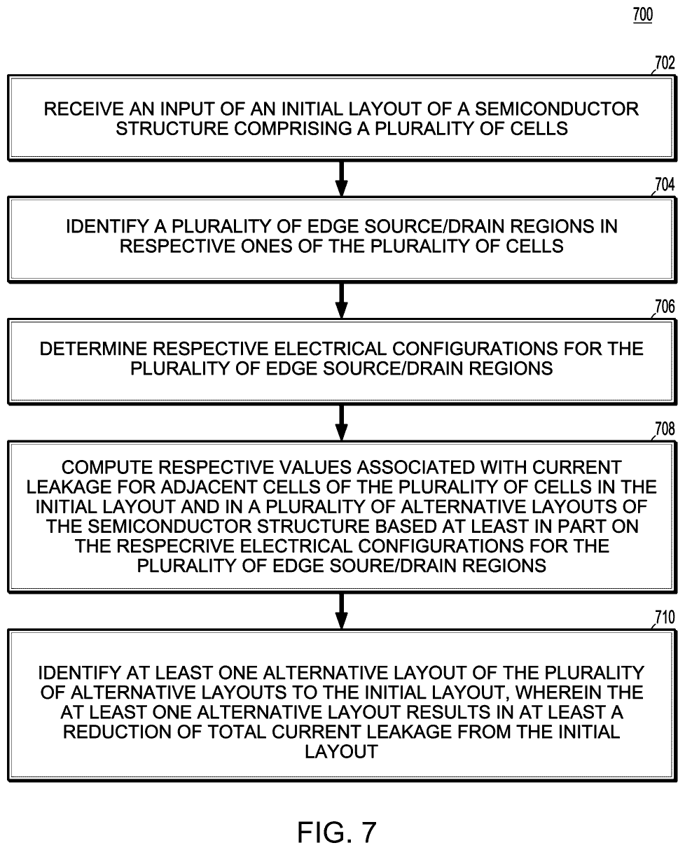

FIG. 6 schematically illustrates a computing system 600 that is configured to generate cell layouts that limit leakage of devices in continuous active configurations. The computing system 600 comprises a controller 601, a semiconductor device manufacturing system 602 and a leakage reduction engine 610. The leakage reduction engine 610 includes a user interface 611, an input/output layer 612, an edge source/drain (S/D) region identification layer 613, a cell abstraction layer 614, a cost function computation layer 615, a cell layout layer 616 and a total leakage computation layer 617.

The semiconductor device manufacturing system 602 applies the alternative cell layout generated by the leakage reduction engine 610 to fabricate a semiconductor structure (e.g., integrated circuit devices comprising, for example, transistors, capacitors, memories, etc. on a silicon wafer) based at least in part on the alternative cell layout. It is to be understood that the semiconductor device manufacturing system 602 may comprise various semiconductor processing stations for performing fabrication tasks such as, but not necessarily limited to, etching, photolithography, chemical mechanical planarization (CMP), deposition, etc., under the control of, for example, controller 601. The controller 601 may comprise, for example, a desktop computer, a laptop computer, a tablet computer, or other type of computing device comprising software and/or applications configured to control semiconductor manufacturing operations.

In accordance with the above-described techniques, the leakage reduction engine 610 generates cell layouts that limit leakage of devices in continuous active configurations. The generated cell layouts are used by the semiconductor device manufacturing system 602 to manufacture semiconductor devices in accordance with the layouts. In more detail, referring to the process 700 for generating cell layouts that limit leakage of devices in continuous active configurations, in connection with step 702, the input/output layer 612 receives an input of an initial layout of a semiconductor structure comprising a plurality of cells. In connection with steps 704 and 706, the edge source/drain region identification layer 613 identifies a plurality of edge source/drain regions in respective ones of the plurality of cells and determines respective electrical configurations for the plurality of edge source/drain regions. The respective electrical configurations for the plurality of edge source/drain regions may comprise at least one of a power connection, a signal connection and a floating configuration. In connection with step 708, the cost function computation layer 615 computes respective values associated with current leakage for adjacent cells of the plurality of cells in the initial layout and in a plurality of alternative layouts of the semiconductor structure based at least in part on the respective electrical configurations for the plurality of edge source/drain regions, and, in connection with step 710, the cell layout layer 616 identifies at least one alternative layout of the plurality of alternative layouts to the initial layout. The at least one alternative layout results in at least a reduction of total current leakage from the initial layout.

In computing the respective values associated with the current leakage for the adjacent cells, the cost function computation layer 615 identifies electrical configurations of respective edge source/drain regions of a plurality of pairs of the adjacent cells. The respective values associated with current leakage for the adjacent cells are computed based on the electrical configurations of the respective edge source/drain regions of the plurality of pairs of the adjacent cells.

In computing the respective values associated with the current leakage for the adjacent cells, the cell abstraction layer 614 generates an abstract view of the electrical configurations of the respective edge source/drain regions of the plurality of pairs of the adjacent cells. The respective values associated with the current leakage for the adjacent cells vary based on a type and a combination of the electrical configurations of the respective edge source/drain regions of the plurality of pairs of the adjacent cells. For example, the respective values associated with the current leakage for the adjacent cells vary based on the abutments.

In computing the respective values associated with the current leakage for the adjacent cells, the cost function computation layer 615 is configured to identify a plurality of gate tie-down structures in the initial layout and in the plurality of alternative layouts. The plurality of edge source/drain regions correspond to at least a subset of the plurality of gate tie-down structures.

In identifying the at least one alternative layout of the plurality of alternative layouts to the initial layout, the cell layout layer bases the identification of the at least one alternative layout on one or more parameters in addition to the reduction of the total current leakage. The one or more parameters include at least one of wire length, frequency and area of one or more devices in the semiconductor structure.

The total leakage computation layer 617 computes a total current leakage of the at least one alternative layout. In an illustrative embodiment, the computing of the total current leakage of the at least one alternative layout comprises identifying a plurality of gate tie-down structures in the at least one alternative layout, identifying respective ones of the plurality of edge source/drain regions corresponding to at least a subset of the plurality of gate tie-down structures, identifying electrical configurations of the respective ones of the plurality of edge source/drain regions of a plurality of pairs of adjacent cells in the at least one alternative layout, computing leakage values for the respective ones of the plurality of pairs of the adjacent cells in the at least one alternative layout based at least in part on the electrical configurations of the respective ones of the plurality of edge source/drain regions, and adding the leakage values for the respective ones of the plurality of pairs of the adjacent cells in the at least one alternative layout.

The input/output layer 612 outputs the at least one alternative layout to the semiconductor device manufacturing system 602 so that the semiconductor device manufacturing system 602 can apply the at least one alternative layout in connection with fabricating the semiconductor structure based at least in part on the at least one alternative layout. In some embodiments, the leakage reduction engine 610, via the user interface 611, enables entry of cell layout by a user. The user interface 611 may comprise, for example, a graphical user interface (GUI).

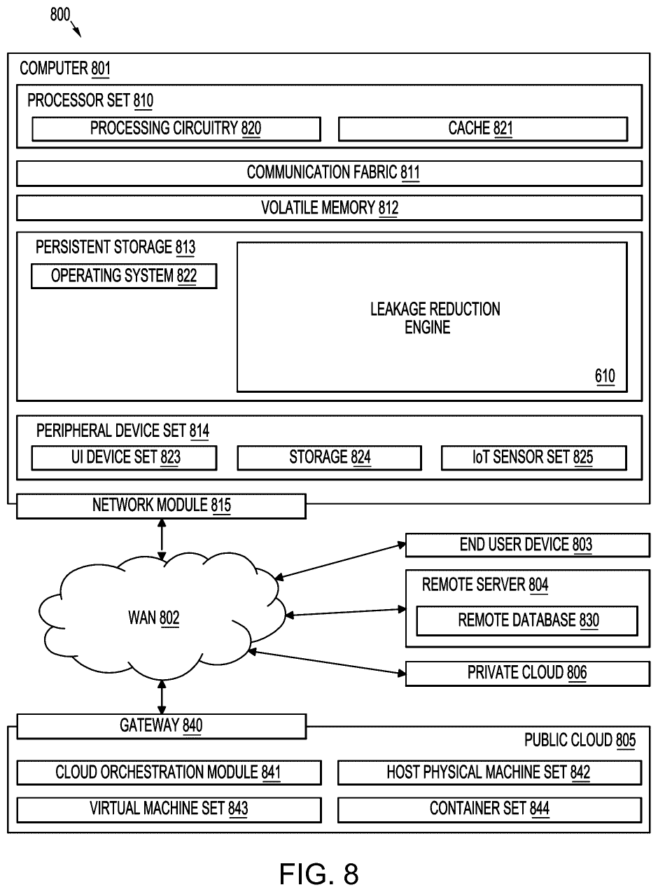

The computing system 600 comprises a software and hardware platform which comprises various software layers that are configured to perform various functions, including, but not limited to, generating cell layouts that limit leakage of devices in continuous active configurations. In addition, the computing system 600 comprises a hardware architecture of processors, memory, etc., which is configured to control the generation of cell layouts that limit leakage of devices in continuous active configurations. In some exemplary embodiments, the computing system 600 may be implemented using any suitable computing system architecture (e.g., as shown in FIG. 8) which is configured to implement methods to support generating cell layouts that limit leakage of devices in continuous active configurations by executing computer readable program instructions that are embodied on a computer program product which includes a computer readable storage medium (or media) having such computer readable program instructions thereon for causing a processor to perform the methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 800 of FIG. 8 contains an example of an environment for the execution of at least some of the computer code involved in performing the inventive methods, such as program code for generating cell layouts that limit leakage of devices in continuous active configurations, which includes identifying a plurality of edge source/drain regions in respective ones of the plurality of cells, determining respective electrical configurations for the plurality of edge source/drain regions, and computing respective values associated with current leakage for adjacent cells of the plurality of cells in the initial layout and in a plurality of alternative layouts of the semiconductor structure to identify at least one alternative layout to the initial layout that results in at least a reduction of total current leakage from the initial layout, as discussed above. In addition to block 610 (leakage reduction engine), computing environment 800 includes, for example, computer 801, wide area network (WAN) 802, end user device (EUD) 803, remote server 804, public cloud 805, and private cloud 806. In this embodiment, computer 801 includes processor set 810 (including processing circuitry 820 and cache 821), communication fabric 811, volatile memory 812, persistent storage 813 (including operating system 822 and block 610, as identified above), peripheral device set 814 (including user interface (UI), device set 823, storage 824, and Internet of Things (IoT) sensor set 825), and network module 815. Remote server 804 includes remote database 830. Public cloud 805 includes gateway 840, cloud orchestration module 841, host physical machine set 842, virtual machine set 843, and container set 844.

Computer 801 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 830. As is well understood in the art of computer technology, and depending upon the technology, performance of a computer-implemented method may be distributed among multiple computers and/or between multiple locations. On the other hand, in this presentation of computing environment 800, detailed discussion is focused on a single computer, specifically computer 801, to keep the presentation as simple as possible. Computer 801 may be located in a cloud, even though it is not shown in a cloud in FIG. 8. On the other hand, computer 801 is not required to be in a cloud except to any extent as may be affirmatively indicated.

Processor set 810 includes one, or more, computer processors of any type now known or to be developed in the future. Processing circuitry 820 may be distributed over multiple packages, for example, multiple, coordinated integrated circuit chips. Processing circuitry 820 may implement multiple processor threads and/or multiple processor cores. Cache 821 is memory that is located in the processor chip package(s) and is typically used for data or code that should be available for rapid access by the threads or cores running on processor set 810. Cache memories are typically organized into multiple levels depending upon relative proximity to the processing circuitry. Alternatively, some, or all, of the cache for the processor set may be located “off chip.” In some computing environments, processor set 810 may be designed for working with qubits and performing quantum computing.

Computer readable program instructions are typically loaded onto computer 801 to cause a series of operational steps to be performed by processor set 810 of computer 801 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 821 and the other storage media discussed below. The program instructions, and associated data, are accessed by processor set 810 to control and direct performance of the inventive methods. In computing environment 800, at least some of the instructions for performing the inventive methods may be stored in block 610 in persistent storage 813.

Communication fabric 811 is the signal conduction path that allow the various components of computer 801 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 812 is any type of volatile memory now known or to be developed in the future. Examples include dynamic type random access memory (RAM) or static type RAM. Typically, the volatile memory is characterized by random access, but this is not required unless affirmatively indicated. In computer 801, the volatile memory 812 is located in a single package and is internal to computer 801, but, alternatively or additionally, the volatile memory may be distributed over multiple packages and/or located externally with respect to computer 801.

Persistent storage 813 is any form of non-volatile storage for computers that is now known or to be developed in the future. The non-volatility of this storage means that the stored data is maintained regardless of whether power is being supplied to computer 801 and/or directly to persistent storage 813. Persistent storage 813 may be a read only memory (ROM), but typically at least a portion of the persistent storage allows writing of data, deletion of data and re-writing of data. Some familiar forms of persistent storage include magnetic disks and solid-state storage devices. Operating system 822 may take several forms, such as various known proprietary operating systems or open-source Portable Operating System Interface type operating systems that employ a kernel. The code included in block 610 typically includes at least some of the computer code involved in performing the inventive methods.

Peripheral device set 814 includes the set of peripheral devices of computer 801. Data communication connections between the peripheral devices and the other components of computer 801 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 823 may include components such as a display screen, speaker, microphone, wearable devices (such as goggles and smart watches), keyboard, mouse, printer, touchpad, game controllers, and haptic devices. Storage 824 is external storage, such as an external hard drive, or insertable storage, such as an SD card. Storage 824 may be persistent and/or volatile. In some embodiments, storage 824 may take the form of a quantum computing storage device for storing data in the form of qubits. In embodiments where computer 801 is required to have a large amount of storage (for example, where computer 801 locally stores and manages a large database) then this storage may be provided by peripheral storage devices designed for storing very large amounts of data, such as a storage area network (SAN) that is shared by multiple, geographically distributed computers. IoT sensor set 825 is made up of sensors that can be used in Internet of Things applications. For example, one sensor may be a thermometer and another sensor may be a motion detector.

Network module 815 is the collection of computer software, hardware, and firmware that allows computer 801 to communicate with other computers through WAN 802. Network module 815 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 815 are performed on the same physical hardware device. In other embodiments (for example, embodiments that utilize software-defined networking (SDN)), the control functions and the forwarding functions of network module 815 are performed on physically separate devices, such that the control functions manage several different network hardware devices. Computer readable program instructions for performing the inventive methods can typically be downloaded to computer 801 from an external computer or external storage device through a network adapter card or network interface included in network module 815.

WAN 802 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 803 is any computer system that is used and controlled by an end user (for example, a customer of an enterprise that operates computer 801), and may take any of the forms discussed above in connection with computer 801. EUD 803 typically receives helpful and useful data from the operations of computer 801. For example, in a hypothetical case where computer 801 is designed to provide a recommendation to an end user, this recommendation would typically be communicated from network module 815 of computer 801 through WAN 802 to EUD 803. In this way, EUD 803 can display, or otherwise present, the recommendation to an end user. In some embodiments, EUD 803 may be a client device, such as thin client, heavy client, mainframe computer, desktop computer and so on.

Remote server 804 is any computer system that serves at least some data and/or functionality to computer 801. Remote server 804 may be controlled and used by the same entity that operates computer 801. Remote server 804 represents the machine(s) that collect and store helpful and useful data for use by other computers, such as computer 801. For example, in a hypothetical case where computer 801 is designed and programmed to provide a recommendation based on historical data, then this historical data may be provided to computer 801 from remote database 830 of remote server 804.

Public cloud 805 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 805 is performed by the computer hardware and/or software of cloud orchestration module 841. The computing resources provided by public cloud 805 are typically implemented by virtual computing environments that run on various computers making up the computers of host physical machine set 842, which is the universe of physical computers in and/or available to public cloud 805. The virtual computing environments (VCEs) typically take the form of virtual machines from virtual machine set 843 and/or containers from container set 844. It is understood that these VCEs may be stored as images and may be transferred among and between the various physical machine hosts, either as images or after instantiation of the VCE. Cloud orchestration module 841 manages the transfer and storage of images, deploys new instantiations of VCEs and manages active instantiations of VCE deployments. Gateway 840 is the collection of computer software, hardware, and firmware that allows public cloud 805 to communicate through WAN 802.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 806 is similar to public cloud 805, except that the computing resources are only available for use by a single enterprise. While private cloud 806 is depicted as being in communication with WAN 802, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 805 and private cloud 806 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A device, comprising:
memory that is configured to store program instructions; and
processing circuitry, coupled to the memory, and configured to execute the program instructions to perform a process to limit current leakage, wherein in performing the process, the processing circuitry is configured to:
receive an input of an initial layout of a semiconductor structure comprising a plurality of cells;
identify a plurality of edge source/drain regions in respective ones of the plurality of cells;
determine respective electrical configurations for the plurality of edge source/drain regions;
compute respective values associated with current leakage for adjacent cells of the plurality of cells in the initial layout and in a plurality of alternative layouts of the semiconductor structure based at least in part on the respective electrical configurations for the plurality of edge source/drain regions; and
identify at least one alternative layout of the plurality of alternative layouts to the initial layout, wherein the at least one alternative layout results in at least a reduction of total current leakage from the initial layout.

2. The device of claim 1, wherein the respective electrical configurations for the plurality of edge source/drain regions comprise at least one of a power connection, a signal connection and a floating configuration.

3. The device of claim 1, wherein, in computing the respective values associated with the current leakage for the adjacent cells, the processing circuitry is configured to identify electrical configurations of respective edge source/drain regions of a plurality of pairs of the adjacent cells, wherein the respective values associated with current leakage for the adjacent cells are computed based on the electrical configurations of the respective edge source/drain regions of the plurality of pairs of the adjacent cells.

4. The device of claim 3, wherein, in computing the respective values associated with the current leakage for the adjacent cells, the processing circuitry is configured to generate an abstract view of the electrical configurations of the respective edge source/drain regions of the plurality of pairs of the adjacent cells.

5. The device of claim 3, wherein the respective values associated with the current leakage for the adjacent cells vary based on a type and a combination of the electrical configurations of the respective edge source/drain regions of the plurality of pairs of the adjacent cells.

6. The device of claim 3, wherein, in computing the respective values associated with the current leakage for the adjacent cells, the processing circuitry is configured to identify a plurality of gate tie-down structures in the initial layout and in the plurality of alternative layouts, and wherein the plurality of edge source/drain regions correspond to at least a subset of the plurality of gate tie-down structures.

7. The device of claim 1, wherein, in identifying the at least one alternative layout of the plurality of alternative layouts to the initial layout, the processing circuitry is configured to further base the identification of the at least one alternative layout on one or more parameters in addition to the reduction of the total current leakage.

8. The device of claim 7, wherein the one or more parameters comprise at least one of wire length, frequency and area of one or more devices in the semiconductor structure.

9. The device of claim 1, wherein the processing circuitry is further configured to compute a total current leakage of the at least one alternative layout, wherein the computing of the total current leakage of the at least one alternative layout comprises:
identifying a plurality of gate tie-down structures in the at least one alternative layout;
identifying respective ones of the plurality of edge source/drain regions corresponding to at least a subset of the plurality of gate tie-down structures;
identifying electrical configurations of the respective ones of the plurality of edge source/drain regions of a plurality of pairs of adjacent cells in the at least one alternative layout;
computing leakage values for the respective ones of the plurality of pairs of the adjacent cells in the at least one alternative layout based at least in part on the electrical configurations of the respective ones of the plurality of edge source/drain regions; and
adding the leakage values for the respective ones of the plurality of pairs of the adjacent cells in the at least one alternative layout.

10. The device of claim 1, wherein the processing circuitry is configured to apply the at least one alternative layout to a semiconductor manufacturing system adapted to fabricate the semiconductor structure based at least in part on the at least one alternative layout.

11. A system, comprising:
a computing system, wherein the computing system comprises memory that is configured to store program instructions, and processing circuitry, coupled to the memory, and configured to execute the program instructions to perform a process to limit current leakage, wherein in performing the process, the processing circuitry is configured to:
receive an input of an initial layout of a semiconductor structure comprising a plurality of cells;
identify a plurality of edge source/drain regions in respective ones of the plurality of cells;
determine respective electrical configurations for the plurality of edge source/drain regions;
compute respective values associated with current leakage for adjacent cells of the plurality of cells in the initial layout and in a plurality of alternative layouts of the semiconductor structure based at least in part on the respective electrical configurations for the plurality of edge source/drain regions; and
identify at least one alternative layout of the plurality of alternative layouts to the initial layout, wherein the at least one alternative layout results in at least a reduction of total current leakage from the initial layout.

12. The system of claim 11, wherein the respective electrical configurations for the plurality of edge source/drain regions comprise at least one of a power connection, a signal connection and a floating configuration.

13. The system of claim 11, wherein, in computing the respective values associated with the current leakage for the adjacent cells, the processing circuitry is configured to identify electrical configurations of respective edge source/drain regions of a plurality of pairs of the adjacent cells, wherein the respective values associated with current leakage for the adjacent cells are computed based on the electrical configurations of the respective edge source/drain regions of the plurality of pairs of the adjacent cells.

14. The system of claim 13, wherein, in computing the respective values associated with the current leakage for the adjacent cells, the processing circuitry is configured to identify a plurality of gate tie-down structures in the initial layout and in the plurality of alternative layouts, and wherein the plurality of edge source/drain regions correspond to at least a subset of the plurality of gate tie-down structures.

15. The system of claim 11, wherein the processing circuitry is further configured to compute a total current leakage of the at least one alternative layout, wherein the computing of the total current leakage of the at least one alternative layout comprises:
identifying a plurality of gate tie-down structures in the at least one alternative layout;
identifying respective ones of the plurality of edge source/drain regions corresponding to at least a subset of the plurality of gate tie-down structures;
identifying electrical configurations of the respective ones of the plurality of edge source/drain regions of a plurality of pairs of adjacent cells in the at least one alternative layout;
computing leakage values for the respective ones of the plurality of pairs of the adjacent cells in the at least one alternative layout based at least in part on the electrical configurations of the respective ones of the plurality of edge source/drain regions; and
adding the leakage values for the respective ones of the plurality of pairs of the adjacent cells in the at least one alternative layout.

16. The system of claim 11, further comprising a semiconductor manufacturing system adapted to fabricate the semiconductor structure based at least in part on the at least one alternative layout.

17. A computer program product for performing a process to limit current leakage, the computer program product comprising:
one or more computer readable storage media, and program instructions collectively stored on the one or more computer readable storage media, the program instructions comprising:
program instructions to receive an input of an initial layout of a semiconductor structure comprising a plurality of cells;
program instructions to identify a plurality of edge source/drain regions in respective ones of the plurality of cells;
program instructions to determine respective electrical configurations for the plurality of edge source/drain regions;
program instructions to compute respective values associated with current leakage for adjacent cells of the plurality of cells in the initial layout and in a plurality of alternative layouts of the semiconductor structure based at least in part on the respective electrical configurations for the plurality of edge source/drain regions; and
program instructions to identify at least one alternative layout of the plurality of alternative layouts to the initial layout, wherein the at least one alternative layout results in at least a reduction of total current leakage from the initial layout.

18. The computer program product of claim 17, wherein the respective electrical configurations for the plurality of edge source/drain regions comprise at least one of a power connection, a signal connection and a floating configuration.

19. The computer program product of claim 17, wherein the program instructions to compute the respective values associated with the current leakage for the adjacent cells comprise program instructions to identify electrical configurations of respective edge source/drain regions of a plurality of pairs of the adjacent cells, wherein the respective values associated with current leakage for the adjacent cells are computed based on the electrical configurations of the respective edge source/drain regions of the plurality of pairs of the adjacent cells.

20. The computer program product of claim 19, wherein the program instructions to compute the respective values associated with the current leakage for the adjacent cells comprise program instructions to identify a plurality of gate tie-down structures in the initial layout and in the plurality of alternative layouts, and wherein the plurality of edge source/drain regions correspond to at least a subset of the plurality of gate tie-down structures.
